(19) United States
(12) Patent Application Publication
(10) Pub. No.: US 2025/0070073 A1
(43) Pub. Date: Feb. 27, 2025

(54) EMBEDDED SEMICONDUCTOR PACKAGING DEVICE

(71) Applicant: Phoenix Pioneer Technology Co., Ltd., Hsinchu County (TW)

(72) Inventor: CHE-WEI HSU, Hsinchu County (TW)

(21) Appl. No.: 18/781,678

(22) Filed: Jul. 23, 2024

(30) Foreign Application Priority Data
Aug. 25, 2023 (TW) 112209142

(51) Int. Cl. H01L 23/00; H01L 23/31; H01L 23/495; H01L 25/16

(52) U.S. Cl. CPC H01L 24/32; H01L 23/3107; H01L 23/49537; H01L 25/16; H01L 2224/26145; H01L 2224/32245

(57) ABSTRACT

The invention provides an embedded semiconductor packaging device, which includes a base, a chip, a frame surrounding structure, and an encapsulation layer. The base has a bonding surface. The chip has a top surface and a bottom surface opposite to each other, wherein the bottom surface is bonded to the bonding surface of the base through an adhesive layer. The frame surrounding structure is arranged along the periphery of a top surface of the chip. The encapsulation layer covers the chip and the frame surrounding structure.

### CROSS-REFERENCE TO RELATED APPLICATION

This application claims the priority benefit of Taiwan application (112209142), filed on Aug. 25, 2023. The entirety of the above-mentioned patent application is hereby incorporated by reference herein and made a part of this specification.

### FIELD OF THE INVENTION

The present invention is related to a semiconductor packaging component, especially relates to an embedded semiconductor packaging device.

### BACKGROUND OF THE INVENTION

Referring to FIG. 1, a semiconductor packaging device 10 includes a first conductive layer 11, a chip 12, an adhesive material 13, a conductive pillar layer 14, a second conductive layer 15, and an encapsulation material 16. The chip 12 is connected to the first conductive layer 11 through an adhesive material 13. The conductive pillar layer 14 includes a plurality of first conductive pillar 141 and a plurality of second conductive pillar 142. The first conductive pillar 141 is arranged between the first conductive layer 11 and the second conductive layer 15. The second conductive pillar 142 is arranged between the chip 12 and the second conductive layer 15. The first conductive layer 11, the chip 12, the adhesive materials 13, the conductive pillar layer 14, and the second conductive layer 15 are encapsulated in the encapsulation material 16.

The adhesive material 13 of the semiconductor packaging device 10 is in a fluid state before it is solidified. During the manufacturing process such as placing the chip 12 on the first conductive layer 11, the adhesive material 13 may be extruded and overflow to the surroundings and climb upward. As shown in the region A in FIG. 1, when the spilled adhesive material 13 climbs upwards to the top surface 121 of the chip 12, it may result in an electrical short circuit or reduce electrical conductivity.

Therefore, how to provide an embedded semiconductor packaging device to avoid the above problems is one of the important issues at present.

### SUMMARY OF THE INVENTION

One objective of this invention is to provide an embedded semiconductor packaging device that can improve the conductivity problem caused by the adhesive material of the package.

To achieve the above purpose, the present invention provides an embedded semiconductor packaging device, which includes a base, a chip, a frame surrounding structure, and an encapsulation layer. The base has a bonding surface. The chip has a top surface and a bottom surface opposite to each other, wherein the bottom surface is bonded to the bonding surface of the base through an adhesive layer. The frame surrounding structure is arranged along a periphery of the top surface of the chip. The encapsulation layer covers the chip and the frame surrounding structure.

In one embodiment, the base is a metal base.

In one embodiment, the aforementioned embedded semiconductor packaging device further includes a conductive build-up structure. A part of the conductive build-up structure is covered in the encapsulation layer, and the other part of the conductive build-up structure is exposed on one surface of the encapsulation layer.

In one embodiment, the conductive build-up structure includes a conductive circuit layer and a conductive pillar layer. The conductive circuit layer is parallel to the bonding surface of the base and arranged in the encapsulation layer above the top surface of the chip. The conductive pillar layer is electrically connected between the top surface of the chip and the conductive circuit layer.

In one embodiment, a height of the frame surrounding structure is less than a height from the top surface of the chip to a bottom surface of the conductive circuit layer.

In one embodiment, the base is a part of the conductive build-up structure.

In one embodiment, a material of the frame surrounding structure is an insulating material.

In one embodiment, the embedded semiconductor packaging device is a packaging member applied to panel-level packaging.

The embedded semiconductor packaging device of this invention uses a frame surrounding structure on the top surface of the chip to frame the electrical contacts of the chip. Therefore, during the process of chip attachment, the difficulty of contamination of the chip top surface due to the extrusion effect that leads to the climb up of the adhesive layer is greatly increased. The adhesive layer is located between the bottom surface of the chip and the base. And, because the contamination caused by the adhesive layer to the packaging structure is reduced, the processing parameters of production can be broadened and the production yield can be improved.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

The present invention will become more readily apparent to those ordinarily skilled in the art after reviewing the following detailed description and accompanying drawings, in which:

FIG. 1 is a schematic diagram of a semiconductor packaging device in prior art;

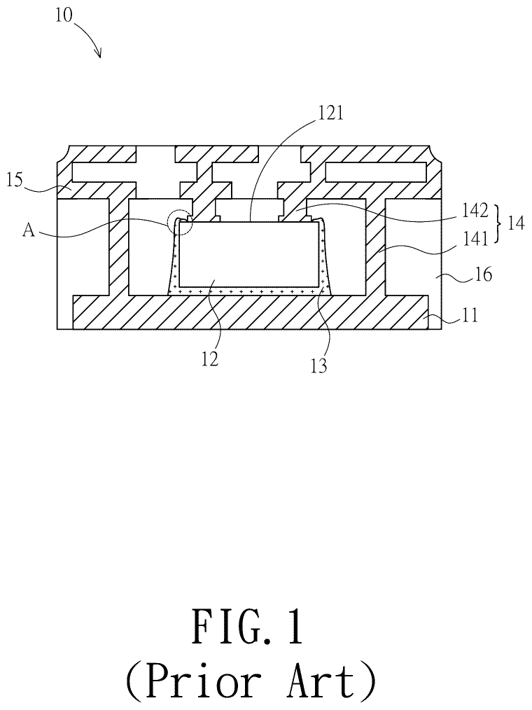

FIG. 2 is a schematic diagram of an embedded semiconductor packaging device according to a preferred embodiment of the present invention;

FIG. 3 is a schematic top view of a chip containing a frame surrounding structure; and

FIG. 4 is a schematic diagram of an embedded semiconductor packaging device according to another preferred embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

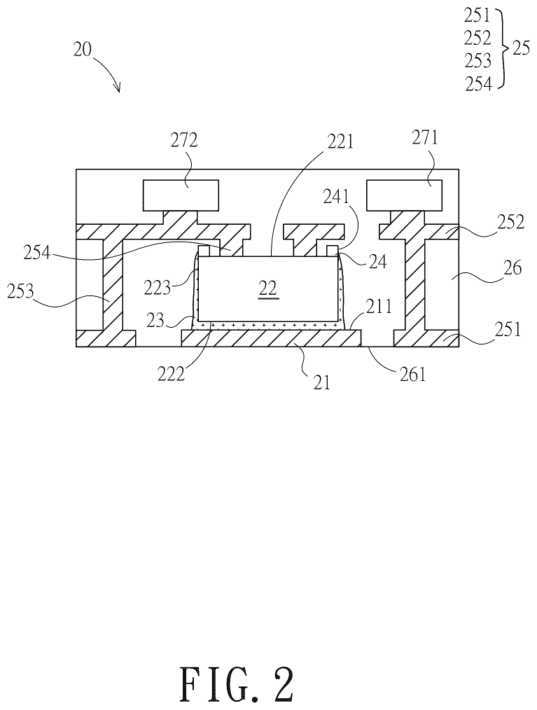

Referring to FIG. 2, an embedded semiconductor packaging device 20 according to a preferred embodiment of the present invention includes a base 21, a chip 22, an adhesive layer 23, a frame surrounding structure 24, a conductive build-up structure 25, and an encapsulation layer 26. The embedded semiconductor packaging device 20 is a packaging member applied to a panel-level packaging (PLP), that is, the embedded semiconductor packaging device 20 is generated through a large-area manufacturing process, which reorganizes the dies on a rectangular panel that is larger than the wafer size and directly processes thereon to save costs and improve packaging efficiency.

The base 21 is a metal base and has a bonding surface 211. In some embodiments, the base 21 may be made of other material(s), such as epoxy or similar non-conductive material(s).

The chip 22 has a top surface 221 and a bottom surface 222 opposite to each other. The chip 22 can be a micro component IC, a memory IC, or a logical IC, etc., and the invention is not limited thereto. In this embodiment, the top surface 221 of the chip 22 is an active surface with a plurality of electrical contact pads that is used for input and output of the signal(s), and the bottom surface 222 of the chip 22 is a non-active surface that can be the electrically conductive or electrically non-conductive electrical contact pads.

The adhesive layer 23 is arranged between the bottom surface 222 of the chip 22 and the bonding surface 211 of the base 21 to fix the chip 22 on the base 21.

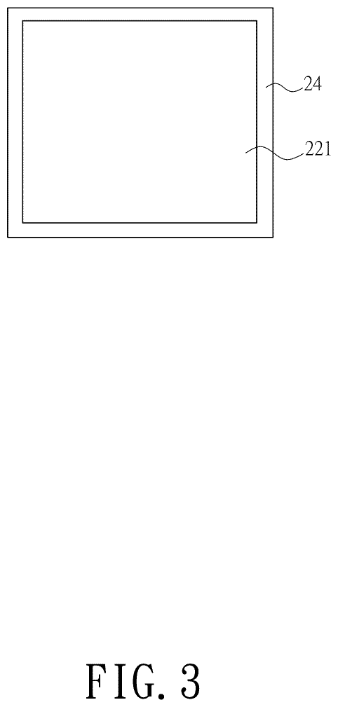

Please refer to FIGS. 2 and 3 together, wherein FIG. 3 is a schematic top view of a chip 22 on which a frame surrounding structure 24 is arranged. The material of the frame surrounding structure 24 is an insulating material, such as but not limited to Polyimide (PI), Silicon Nitride (SiN), Epoxy, Underfill, Solder Mask or Photosensitive Dielectric Material(s). The frame surrounding structure 24 is arranged along the periphery of the top surface 221 of the chip 22 to form a three-dimensional insulated wall structure. In this embodiment, a height of the frame surrounding structure 24 is greater than a height of the electrical contact pad(s) (not shown in the figure) of the top surface 221 of the chip 22. In addition, one side surface 241 of the frame surrounding structure 24 is flush and coplanar with one side surface 223 of the chip 22. In some embodiments, the frame surrounding structure 24 can narrow toward the center of the chip 22.

Please continue to refer to FIG. 2. The conductive build-up structure 25 includes a first conductive circuit layer 251, a second conductive circuit layer 252, a first conductive pillar 253, and a second conductive pillar 254. In this embodiment, the first conductive circuit layer 251 and the base 21 are the same layer structure, in other words, the base 21 is a part of the first conductive circuit layer 251. The second conductive circuit layer 252 is arranged above the top surface 221 of the chip 22. The surface of the first conductive circuit layer 251 and the second conductive circuit layer 252 is approximately parallel to the bonding surface 211 of the base 21. The first conductive pillar 253 is arranged between the first conductive circuit layer 251 and the second conductive circuit layer 252. The second conductive pillar 254 is arranged between the top surface 221 of the chip 22 and the second conductive circuit layer 252. It is worth to mention that the best embodiment of the frame surrounding structure 24 is that the height of the frame surrounding structure 24 is less than the height of the top surface 221 of the chip 22 to the bottom surface of the second conductive circuit layer 252, that is, there is a dielectric material between those two surfaces to avoid affecting the structural state of the second conductive circuit layer 252. In some embodiments, for example, when the composition of the frame surrounding structure 24 includes but is not limited to the photosensitive dielectric material(s), a height of the frame surrounding structure 24 may be equal to a height of the top surface 221 of the chip 22 to a bottom surface of the second conductive circuit layer 252, that is, the two will be in direct contact.

The encapsulation layer 26 covers the chip 22, the adhesive layer 23, and the frame surrounding structure 24. A part of the conductive build-up structure 25 is covered in the encapsulation layer 26, and the other part of the conductive build-up structure 25 is exposed to the encapsulation layer 26. In this embodiment, the surface of the first conductive circuit layer 251 which is part of the conductive build-up structure 25 is exposed to the bottom surface 261 of the encapsulation layer 26, and the remaining conductive build-up structure 25 including the second conductive circuit layer 252, the first conductive pillar 253, and the second conductive pillar 254 are covered in the encapsulation layer 26.

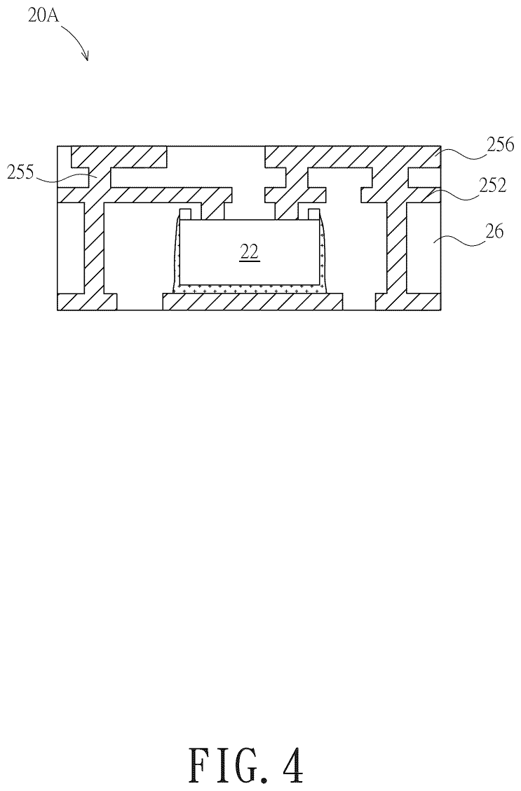

In this embodiment, the side of the second conductive circuit layer 252 away from the chip 22 may also be provided with a plurality of electronic components, which may include, but is not limited to, an active component 271 and a passive component 272. In some embodiments such as the embedded semiconductor packaging device 20A shown in FIG. 4, the side of the second conductive circuit layer 252 away from the chip 22 may be provided with other conductive circuit layers and conductive pillars, such as the third conductive pillar 255 and the third conductive circuit layer 256.

In addition, it should be noted that, in the present embodiment, the frame surrounding structure 24 can be formed on the top surface 221 of the chip 22 through the semiconductor processing technology of etching in photolithography, coating, dispensing, etc., and then the chip 22 loaded with the frame surrounding structure 24 is incorporated into the manufacturing process of the packaging.

In summary, the embedded semiconductor packaging device in this invention uses a frame surrounding structure on the top surface of the chip to enclose the electrical contacts of the chip. Therefore, it can effectively block and prevent the adhesive layer from climbing upward and contaminating the top surface of the chip due to the extrusion effect during the process of chip attachment. Hence, there will be no risk of electrical bridging. In this way, the processing parameters of the adhesive layer application can be broadened (including but not limited to the height of the adhesive layer), and the production yield can also be improved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An embedded semiconductor packaging device, comprising:
a base, having a bonding surface;
a chip, having a top surface and a bottom surface opposite to each other, wherein the bottom surface is bonded to the bonding surface of the base through an adhesive layer;
a frame surrounding structure, arranged along a periphery of the top surface of the chip; and
an encapsulation layer, covering the chip and the frame surrounding structure.

2. The embedded semiconductor packaging device according to claim 1, wherein the base is a metal base.

3. The embedded semiconductor packaging device according to claim 1, furthering comprising a conductive build-up structure, a part of the conductive build-up structure is covered in the encapsulation layer, and the other part of the conductive build-up structure is exposed on one surface of the encapsulation layer.

4. The embedded semiconductor packaging device according to claim 3, wherein the conductive build-up structure comprises:
at least one conductive circuit layer, parallel to the bonding surface of the base and arranged in the encapsulation layer above the top surface of the chip; and
a conductive pillar layer, electrically connected between the top surface of the chip and the conductive circuit layer.

5. The embedded semiconductor packaging device according to claim 4, wherein a height of the frame surrounding structure is less than a height from the top surface of the chip to a bottom surface of the conductive circuit layer.

6. The embedded semiconductor packaging device according to claim 3, wherein the base is a part of the conductive build-up structure.

7. The embedded semiconductor packaging device according to claim 1, wherein a material of the frame surrounding structure is an insulating material.

8. The embedded semiconductor packaging device according to claim 7, wherein the insulating material comprises Polyimide (PI), Silicon Nitride (SiN) or Epoxy.

9. The embedded semiconductor packaging device according to claim 7, wherein the insulating material comprises Underfill, Solder Mask or Photosensitive Dielectric Material(s).

10. The embedded semiconductor packaging device of claim 1, wherein the embedded semiconductor packaging device is a packaging member applied to a panel-level packaging.
